(19) United States
(12) Patent Application Publication
(10) Pub. No.: US 2007/0210806 A1
(43) Pub. Date: Sep. 13, 2007

(54) Fuel cell electric power sensing methodology and the applications thereof

(76) Inventors: Chun-Chin Tung, Taipei (TW); Feng-Yi Deng, Taipei (TW); Yu-Chin Wang, Taipei (TW); Yu-Lin Tang, Taipei (TW)

Correspondence Address: G. LINK CO. LTD, 3550 BELL ROAD, MINOOKA, IL, 60447, US

(21) Appl. No.: 11/331,158

(22) Filed: Mar. 9, 2006

(51) Int. Cl. G01R 27/28

(52) U.S. Cl. 324/618

(57) ABSTRACT

The present invention provides a fuel cell electric power sensing methodology and the applications thereof. A fuel cell electric power sensing methodology comprises the following steps: electrically connecting a fuel cell to a main control circuit, which is a circuit having a voltage/current judgment means and a storage means; computing the rate of change of transient voltage, wherein after starting the fuel cell and supplying electricity load, during the transient state process in which voltage decreases from initial voltage to steady-rate voltage, voltage value of a first reference time and a second reference time are retrieved to compute the rate of change of voltage with time, through a voltage/current judgment means of the main control circuit; testing the correspondence of the change of rate of transient voltage, wherein the main control circuit obtains a steady-state voltage value and a steady-state current value when the fuel cell is at the steady state, through the change of rate of transient voltage stored by the storage means and the correspondence of output voltage and output current of the fuel cell at a specific operating temperature; and testing if the output electricity of the fuel cell meets the rated output, wherein the steady-state voltage value and the steady-state current value at a steady state are obtained during the above steps, and then the main control circuit computes the power for these values, so as to decide if the electricity outputted by the fuel cell meets the rated output.

### FIELD OF THE INVENTION

The present invention relates to a fuel cell electric power sensing methodology and the applications thereof, particularly to a fuel cell electric power sensing methodology in which the electrical characteristics and the operating temperature of a fuel cell can be obtained through a time-voltage characteristics curve of the fuel cell and the correspondence of voltage with the operating temperature, output voltage, and output current of the fuel cell.

### BACKGROUND OF THE INVENTION

A conventional fuel cell comprises a battery core that outputs electricity outputted by electrochemical reactions of hydrogen-rich fuel (such as methanol) and oxygen fuel, and the operating status (such as output voltage/current) of the battery core is achieved through the operating condition settings of the fuel cell core, wherein the electricity generated by the fuel cell is outputted through an electricity network. Generally speaking, this fuel cell needs a control means to monitor the electricity output status thereof. However, when the fuel cell is at a constant current output, starting from the time when it is connected to the time when the load starts, its voltage will gradually decrease till tens of seconds later, when voltage will enter a steady-state constant voltage status, as shown in FIG. 3. However, this takes a very long reaction time, if it is necessary to detect the steady-state voltage/current through a circuit. Therefore, control is not favorable, and moreover, instant monitoring is not possible.

In addition, an electronic system that uses fuel cells generally also uses other electric power output devices, for example, rechargeable secondary lithium batteries, wherein it is necessary to instantly monitor the output power of the fuel cell and adjust the electric power output between the fuel cell and the secondary battery, so as to instantly respond to the load.

In view of the foregoing weakness of the prior art in responding to the output electricity of the fuel cell rapidly, the present inventor has come up with an improved fuel cell electric power sensing methodology, so as to instantly monitor the voltage, current, and power outputted by the fuel cell.

### SUMMARY OF THE INVENTION

It is a primary objective of this invention to provide a fuel cell electric power sensing methodology, so that it is possible to know the voltage, current, and power outputted by the fuel cell, before the fuel cell is at a steady state.

Another objective of the present invention provides a fuel cell electric power sensing methodology, in which it is possible to know the voltage, current, power, and the operating temperature thereof outputted by the fuel cell, through the output characteristics of the fuel cell, in the transient state process of the fuel cell.

Another objective of the present invention is to provide a fuel cell electric power sensing methodology, which is applied in a secondary battery system, and can adjust the electric power output of the secondary battery, by instantly monitoring the electricity output of the fuel cell, so as to obtain the electricity output required for the load.

To achieve the above objectives of the present invention, the present invention provides a fuel cell electric power sensing methodology and the applications thereof. A fuel cell electric power sensing methodology comprises the following steps: electrically connecting a fuel cell to a main control circuit, which is a circuit having a voltage/current judgment means and a storage means; computing the rate of change of transient voltage after the fuel cell has started and supplied electricity load, and during the transient state process in which voltage decreases from initial voltage to steady-rate voltage, and retrieving a voltage value of a first reference time and a second reference time to compute the rate of change of voltage with time, through the voltage/current judgment means of the main control circuit; testing the correspondence of the change of rate of transient voltage, wherein the main control circuit obtains a steady-state voltage value and a steady-state current value when the fuel cell is at a steady state, through the change of rate of transient voltage stored by the storage means and the correspondence between output voltage and output current of the fuel cell at a specific operating temperature; and testing if the electricity outputted by the fuel cell meets the rated output, through which the steady-state voltage values and the steady-state current values at a steady state are obtained by the above steps, and then the main control circuit computes power for these values, so as to decide if the electricity outputted by the fuel cell meets the rated output.

In addition, the present invention can also be applied in fuel cells, and together with other electric power energy output devices, provide multi-energy output.

The main control circuit of the present invention comprises a temperature sensing mechanism, which can retrieve the initial voltage of fuel cell at no load, and then obtain the operating temperature of fuel cell, through the correspondence between the initial voltage of the fuel cell stored by the storage means at no load and the operating temperature of the fuel cell.

### BRIEF DESCRIPTION OF THE DRAWINGS

The above objects and advantages of the present invention will become more apparent with reference to the appended drawings wherein:

FIG. 1 is a schematic view of the relationship of a fuel cell electric power sensing methodology and the applications thereof in a circuit element having a load according to the present invention;

FIG. 2 shows the flow chart of the operations of a system applied in the fuel cell electric power sensing methodology of the present invention;

FIG. 3 is a schematic view of the time-voltage relationship of the fuel cell applied in the present invention since the fuel cell starts and operates till it becomes stable;

FIG. 4 shows a schematic view of the correspondence of the change of rate of transient voltage of the fuel cell of the present invention with the operating temperature, output voltage, and output current of the fuel cell of the present invention;

FIG. 5 shows a schematic view of the relationship of a fuel cell electric power sensing methodology and the applications thereof in a circuit element having a load according to a second embodiment of the present invention;

FIG. 6 shows a flow chart of the operations of a system that applies the fuel cell electric power sensing methodology according to the second embodiment of the present invention.

### DETAILED DESCRIPTION OF THE INVENTION

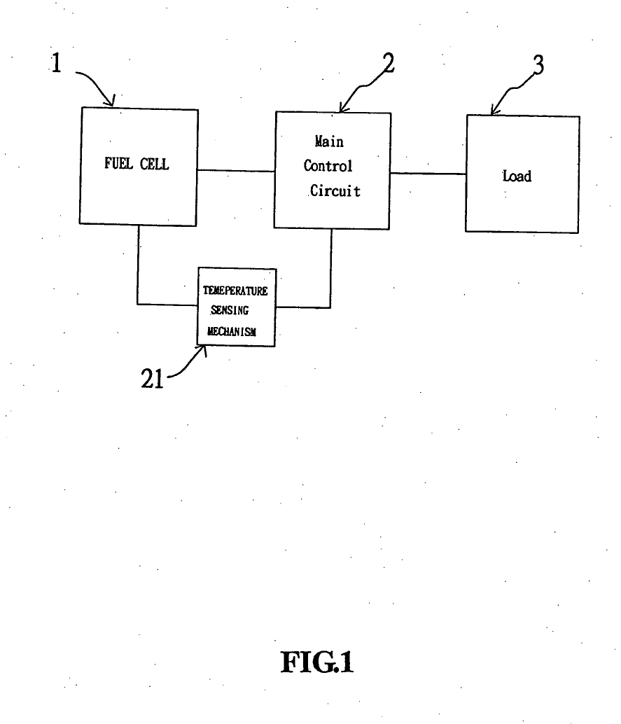

FIG. 1 is a schematic view of the relationship of a fuel cell electric power sensing methodology and the applications thereof in a circuit element having a load according to the present invention. Referring to FIG. 1, a fuel cell (1) of the present invention is electrically connected to a main control circuit (2), which is then electrically connected to a load (3), so that the main control circuit (2) operates the fuel cell (1), and the electricity obtained by converting the fuel cell (1) into voltage is then supplied to the load (3), wherein the fuel cell (1) is an energy converter that generates electricity outputted by electrochemical reactions of hydrogen-rich fuel, oxygen fuel, and catalysts, and can output electricity generated by the fuel cell (1) to the main control circuit (2); the main control circuit (2) is a circuit having a voltage/current judgment means and a storage means, and the voltage/current judgment means computes the change of rate of voltage with time, whereas the storage means stores the change of rate of transient voltage and the correspondence of the output voltage and output current of the fuel cell, and the correspondence can directly exist in a tabulation of values or relations.

The fuel cell (1) is a fuel cell made by the manufacturing process of a printed circuit board.

In addition, in the system that applies the fuel cell electric power sensing methodology of the present invention, the main control circuit (2) can further comprise a temperature sensing mechanism (21), which can be a temperature sensor such as a thermocouple, or any other device capable of sensing temperature, and thus can be used to sense the temperature of the fuel cell (1), and then return the temperature as feedback to the main control circuit (2), so as to provide the operating temperature of the fuel cell (1). Under this condition, the storage means stores the change of rate of transient voltage and the correspondence of the operating temperature, output voltage, and output current of the fuel cell.

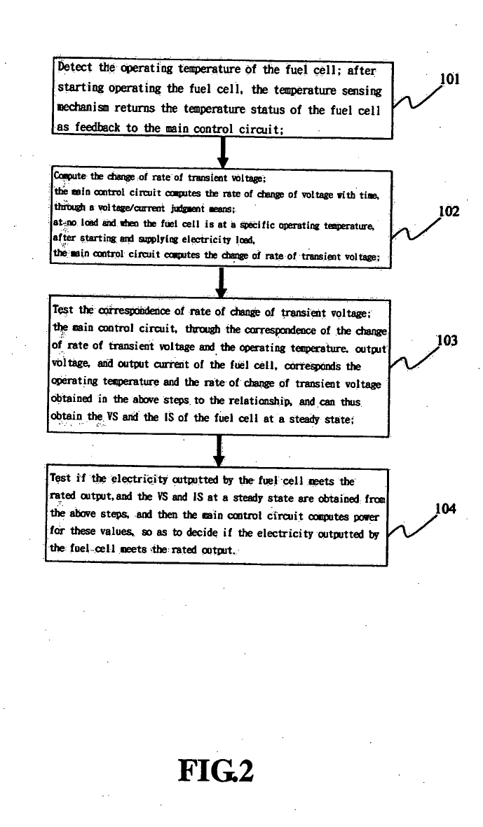

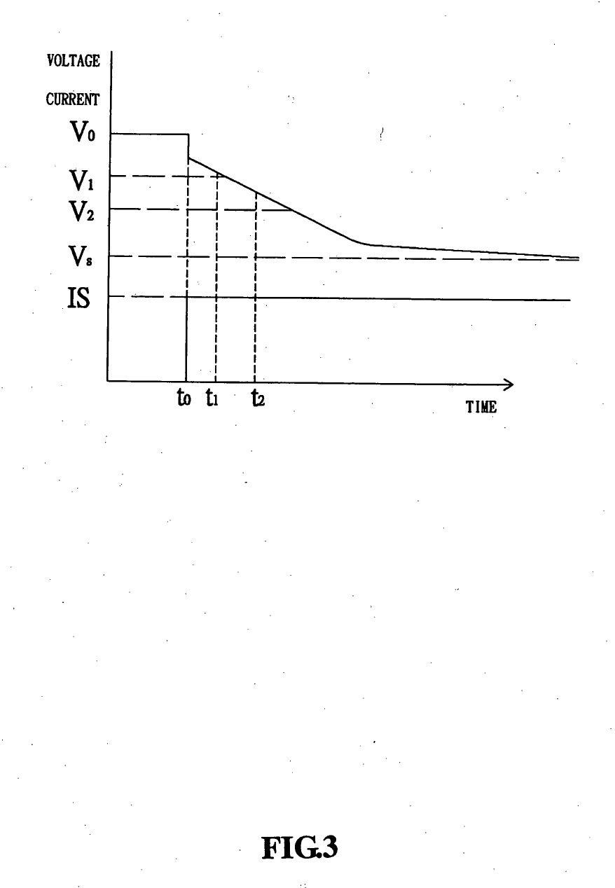

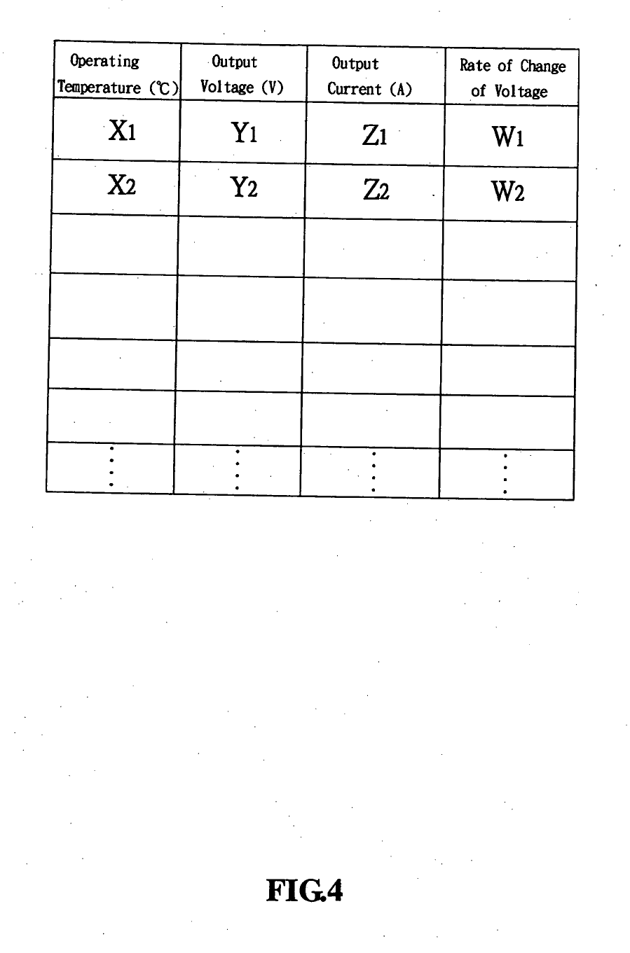

FIG. 2 shows the flow chart of the operations of a system applied in the fuel cell electric power sensing methodology of the present invention. FIG. 3 is a schematic view of the time-voltage relationship of the fuel cell used in the present invention since the fuel cell starts and operates till it becomes stable. FIG. 4 shows a schematic view of the correspondence of the change of rate of transient voltage of the fuel cell of the present invention with the operating temperature, output voltage, and output current of the fuel cell of the present invention. Referring to FIG. 2, the operating steps of the system that applies the fuel cell electric power sensing methodology of the present invention comprises Step 101, Step 102, Step 103, and Step 104. The operating steps of a system that applies the fuel cell electric power sensing methodology comprise: Step 101 is to detect the operating temperature of the fuel cell, wherein when starting operating the fuel cell (1), the temperature sensing mechanism (21) returns the temperature status of the fuel cell (1) as feedback to the main control circuit (2); Step 102 is to compute the change of rate of transient voltage; referring to FIG. 3, the main control circuit (2) computes the rate of change of voltage with time, through a voltage/current judgment means, wherein the initial voltage of the fuel cell (1) is V0, which is at no load and when the fuel cell is at a specific operating temperature, but after the fuel cell (1) starts at time t0 and then supplies electricity load (3), V0 will gradually decrease, and the current is a stable IS (unknown that time); therefore, V1 and V2 corresponding to a first reference time t1 and a second reference time t2 are retrieved respectively, and then, the main control circuit (2) computes the change of rate of transient voltage; Step 103 is to test the correspondence of the rate of change of transient voltage, wherein the main control circuit (2), through the correspondence of the change of rate of transient voltage with the operating temperature, output voltage, and output current of the fuel cell of the present invention as shown in FIG. 4, corresponds the operating temperature and the rate of change of transient voltage obtained in the above steps to the relationship, and can thus obtain the VS and IS value of the fuel cell at a steady state; Step 104 is to test if the electricity outputted by the fuel cell meets the rated output, and the VS and IS at a steady state are obtained from the above steps, and then the main control circuit (2) computes power for these values, so as to decide if the electricity outputted by the fuel cell (1) meets the rated output.

Referring to FIG. 3, the initial voltage of the fuel cell at no load is V0 that corresponds to the characteristics of the fuel cell at a specific operating temperature. Therefore, V0 at no load can be measured by the main control circuit (2), and the storage means stores the initial voltage and the operating temperature of the fuel cell at no load or the correspondence of the output voltage and the output current of the fuel cell, so as to further obtain the operating temperature of the fuel cell. Therefore, the operating temperature of the fuel cell in the above steps can be obtained from detecting V0 of the fuel cell at no load or directly replacing the operating temperature of the fuel cell stored by the storage means in the corresponding relationship with V0.

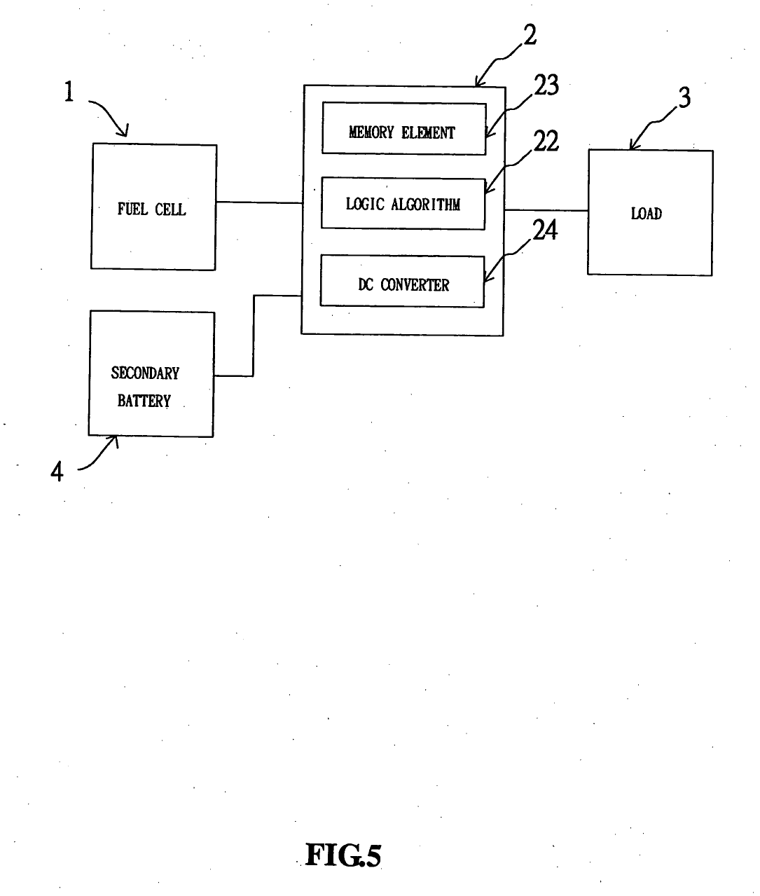

FIG. 5 shows a schematic view of the relationship of a fuel cell electric power sensing methodology and the applications thereof in a circuit element having a load according to a second embodiment of the present invention. Referring to FIG. 5, according to the above embodiment of the present invention, the fuel cell electric power sensing methodology of the present invention can be applied in a secondary battery (4) system, and the main control circuit (2) can further comprise a logic algorithm (22), a memory element (23), and a DC converter (24), wherein the secondary battery (4) is another electric power generating device, which can convert the stored chemical energy into a primary battery or a secondary battery of electrical energy, and then output the electricity generated. For example, the secondary battery (4) can be a primary alkaline battery or a secondary lithium battery. Moreover, in the main control circuit (2), the logic algorithm (22) is a circuit having a voltage/current judgment means and can control the operations of the fuel cell (1) and the secondary battery (4); the memory element (23) is an integrated circuit that provides a storage means to store a variety of the above information; and the DC converter (24) comprises a buck logic means or a boost logic means to meet the voltage required for the load (3), and then the electricity outputted by the fuel cell (1) or the secondary battery (4) is converted into a corresponding voltage.

FIG. 6 shows a flow chart of the operations of a system that applies the fuel cell electric power sensing methodology according to the second embodiment of the present invention. Referring to FIG. 6, the operating steps of the system that applies the fuel cell electric power sensing methodology of the present invention comprises Step 201, Step 202, Step 203, Step 204, and Step 205. According to the second embodiment of the system that applies the fuel cell electric power sensing methodology of the present invention, the operating steps comprise: Step 201 is to detect the operating temperature of the fuel cell, wherein when starting operating the fuel cell (1), the temperature sensing mechanism (21) returns the temperature status of the fuel cell (1) as feedback to the main control circuit (2); Step 202 is to compute the change of rate of transient voltage; referring to FIG. 3, the main control circuit (2) computes the change of rate of voltage with time, through the voltage/current judgment means thereof, wherein the initial voltage of the fuel cell (1) is V0, which is at no load and when the fuel cell is at a specific operating temperature, but after the fuel cell (1) starts at time t0 and then supplies electricity load (3), V0 will gradually decrease, and the current is a stable IS (unknown that time); therefore, V1 and V2 corresponding to a first reference time t1 and a second reference time t2 are retrieved respectively, and then the main control circuit (2) computes the change of rate of transient voltage; Step 203 is to test the correspondence of rate of change of transient voltage, wherein the main control circuit (2), through the correspondence of the change of rate of transient voltage with the operating temperature, output voltage, and output current of the fuel cell of the present invention as shown in FIG. 4, corresponds the operating temperature and the rate of change of transient voltage obtained in the above steps to the relationship, and can thus obtain the VS and the IS of the fuel cell at a steady state; Step 204 is to test if the electricity outputted by the fuel cell is sufficient to supply the load, and to obtain the VS and the IS at a steady state from the above steps, and then the main circuit board (2) computes the power outputted by the fuel cell (1), so as to decide if it meets the required load; Step 205 is to adjust the electricity outputted by the fuel cell, wherein the main control circuit (2) is to decide the power outputted by the fuel cell (1) obtained from the above steps meets the required load (3); when it is still unable to meet the power required for the load (3), even when the power outputted by the fuel cell (1) reaches the maximum output power of the fuel cell, the logic algorithm (22) of the main control circuit (2) will select the parallel electric power supply status of the secondary battery (4) and the fuel cell (1), and simultaneously supply electric power output, and then, the DC converter (24) will convert the electricity outputted by the fuel cell (1) and the secondary battery (4) into a stable voltage and supply it to the load (3).

In addition, according to the above steps, when the fuel cell (1) is sufficient to independently supply electricity required for the load (3), and the logic algorithm (22) can select to terminate the electricity outputted by the secondary battery (4), and select the electricity supply of the fuel cell (1) to the secondary battery (4), for recharging the secondary battery (4).

Moreover, the operating temperature of the fuel cell can be set to be a specific known value, so that it is possible to omit the step of detecting the operating temperature of the fuel cell.

It is to be understood that the foregoing description of the present invention should not be based to restrict the invention, and that all equivalent modifications and variations made without departing from the intent and import of the foregoing description should be included in the following claim.

What is claimed is:

1. A fuel cell electric power sensing methodology, comprising:
electrically connecting a fuel cell to a main control circuit, which is a circuit having a voltage/current judgment means and a storage means;
computing the rate of change of transient voltage, wherein after the fuel cell has been started and has supplied electricity, in the transient state process in which voltage decreases from initial voltage to a steady-state voltage, and retrieving the voltage value of a first reference time and a second reference time, and then the voltage/current judgment means is used to compute the rate of change of voltage with time, through the main control circuit;
testing the correspondence of the change of rate of transient voltage, wherein the main control circuit, through the rate of change of transient voltage stored by the storage means and the correspondence of output voltage and output current of the fuel cell at a specific operating temperature, so as to obtain a steady-state voltage value and a steady-state current value of the fuel cell at a steady state; and
testing if electricity outputted by the fuel cell meets the rated output, wherein the steady-state voltage value and the steady-state current value at a steady state are obtained from the above steps, and then the main control circuit computes the power of these values, so as to decide if the electricity outputted by the fuel cell meets the rated output.

2. The fuel cell electric power sensing methodology as claimed in claim 1, further comprising the following steps:
detecting the operating temperature of the fuel cell, wherein the main control circuit comprises a temperature sensing mechanism, which returns the temperature status of the fuel cell as feedback to the main control circuit, when starting operating the fuel cell; and
for the testing of the correspondence of the rate of change of transient voltage in claim 1, the main control circuit, through the rate of change of transient voltage stored by the storage means and the correspondence of the operating temperature, output voltage, and output current of the fuel cell, obtains the steady-state voltage value and the steady-state current value of the fuel cell at a steady state.

3. The fuel cell electric power sensing methodology as claimed in claim 2, wherein the temperature sensing mechanism is achieved through a temperature sensor.

4. The fuel cell electric power sensing methodology as claimed in claim 3, wherein the temperature sensor can be a thermocouple or any temperature sensor.

5. The fuel cell electric power sensing methodology as claimed in claim 2, wherein the temperature sensing mechanism retrieves initial voltage of the fuel cell at no load, and then obtains the operating temperature of the fuel cell, through the correspondence of the initial voltage and the operating temperature of the fuel cell stored by the storage means at no load.

6. The fuel cell electric power sensing methodology as claimed in claim 2, wherein the temperature sensing mechanism retrieves an initial voltage of the fuel cell at no load, and then the initial voltage replaces the operating temperature of the fuel cell in the correspondence of the rate of change of transient voltage with the operating temperature, output voltage, and output current of the fuel cell stored by the storage means.

7. The fuel cell electric power sensing methodology as claimed in claim 1, further providing a secondary battery; and the main control circuit further comprises a logic algorithm, a memory element, and a DC converter, and moreover, the logic algorithm is a circuit comprising a voltage/current judgment means, so as to control the operations of the fuel cell and the secondary battery; said memory element is an integrated circuit that provides a storage means; and the DC converter selects either a buck logic means or a boost logic means for the voltage required by the load, so as to convert electricity outputted by the fuel cell and the secondary battery to form a corresponding voltage.

8. The fuel cell electric power sensing methodology as claimed in claim 7, wherein the secondary cell can be either a primary battery or a secondary battery.

9. The fuel cell electric power sensing methodology as claimed in claim 7, further comprising the following steps:
obtaining a steady-state voltage and a steady-state current at a steady state from the steps, and computing the power output of the fuel cell by the main control circuit; and
adjusting the electricity outputted by the fuel cell, wherein the main control circuit, through the fuel cell output power obtained from the steps, decides if it meets the required load; when the fuel cell output power is unable to meet the power required for the load even when it reaches the maximum output power of the fuel cell, the logic algorithm of the main control circuit will select the parallel electricity supply status of the secondary battery and the fuel cell, and simultaneously provide electricity output, and then the DC converter will convert the electricity outputted by the fuel cell and the secondary battery into a stable voltage and supply it to the load.

10. The fuel cell electric power sensing methodology as claimed in claim 9, wherein the fuel cell is sufficient to independently supply the electricity required by the load, the logic algorithm can select to terminate electricity outputted by the secondary battery, and then select the supply of electricity by the fuel cell to the secondary battery, for recharging the secondary battery.

11. The fuel cell electric power sensing methodology as claimed in claim 1, wherein the correspondence of the rate of change of transient voltage stored by the storage means and the output voltage and the output current of the fuel cell can directly exist in a tabulation of values or relations.

12. The fuel cell electric power sensing methodology as claimed in claim 1, wherein the fuel cell is a fuel cell made by the manufacturing process of a printed circuit board.

13. The fuel cell electric power sensing methodology as claimed in claim 3, wherein the secondary battery can be a primary battery or a secondary battery.
